(19) United States
(12) Patent Application Publication
(10) Pub. No.: US 2016/0013344 A1
(43) Pub. Date: Jan. 14, 2016

(54) METHOD TO ASSEMBLE A RECTANGULAR CIC FROM A CIRCULAR WAFER

(71) Applicant: Emcore Solar Power, Inc., Albuquerque, NM (US)

(72) Inventors: Greg Flynn, Albuquerque, NM (US); Benjamin Richards, Albuquerque, NM (US)

(21) Appl. No.: 14/498,071

(22) Filed: Sep. 26, 2014

Related U.S. Application Data
(60) Provisional application No. 62/022,556, filed on Jul. 9, 2014.

(51) Int. Cl. H01L 31/05; H01L 31/18; H01L 31/042

(52) U.S. Cl. CPC H01L 31/0504; H01L 31/042; H01L 31/18

(57) ABSTRACT

The method for producing solar cells comprises the step of dividing a non-rectangular solar cell wafer into a plurality of solar cells, the plurality of solar cells comprising at least one solar cell having a first geometric configuration, and at least one solar cell having a second geometric configuration, different from the first geometric configuration. The solar cells can have a rectangular shape and be re-arranged and combined into a rectangular solar cell assembly.

### REFERENCE TO RELATED APPLICATIONS

The present application claims the benefit of U.S. Provisional Application No. 62/022,556 filed Jul. 9, 2014 and is related to U.S. patent application Ser. No. 29/493,998 filed Jun. 16, 2014.

### BACKGROUND OF THE DISCLOSURE

1. Field of the Disclosure

The disclosure relates to the field of photovoltaic power devices.

2. Description of the Related Art

Photovoltaic devices, such as photovoltaic modules or “CICs” (Solar Cell+Interconnects+Coverglass) devices, comprise one or more individual solar cells arranged to produce electric power in response to irradiation by solar light. Sometimes, the individual solar cells are rectangular, often square. Photovoltaic modules, arrays and devices including one or more solar cells are also generally rectangular, for example, based on an array of individual solar cells. Arrays of circular solar cells are known to involve the drawback of inefficient use of the surface on which the solar cells are mounted, due to space that is not covered by the circular solar cells due to the space that is left between adjacent solar cells due to their circular configuration (cf. U.S. Pat. Nos. 4,235,643 and 4,321,417).

Solar cells are often produced from circular or substantially circular wafers. For example, solar cells for space applications are typically multi junction solar cells grown on substantially circular wafers. These circular wafers are usually 100 mm or 150 mm diameter wafers. However, for assembly into a solar array, circular wafers are not preferable. Therefore the circular wafers are often divided into other form factors. The preferable form factor for a solar cell for space is a rectangle, such as a square. However, when a single circular wafer is divided into a single rectangle, the wafer utilization is low. This results in waste.

### SUMMARY OF THE DISCLOSURE

A first aspect of the disclosure relates to a method for producing solar cells, comprising the step of dividing a non-rectangular solar cell wafer into a plurality of solar cells, said plurality of solar cells comprising at least one solar cell having a first geometric configuration and at least one solar cell having a second geometric configuration, the second geometric configuration being different from the first geometric configuration.

In many embodiments of the disclosure, the non-rectangular wafer is a substantially circular wafer. In some embodiments of the disclosure, the substantially circular wafer has a circular cross-section except for a flat segment at its circumference. Wafers of this type are frequently used for the production of solar cells, including solar cells for space applications and CIC devices.

The expression “geometric configuration” refers to the geometric configuration of the solar cell in the plane of the surface intended to receive the solar radiation, that is, the surface corresponding to one of the surfaces of the wafer. The expression “geometric configuration” refers to the shape and size of the solar cell in said plane. Thus, the second geometric configuration can differ from the first geometric configuration in what regards the shape, in what regards the size, or in what regards both aspects. For example, the first geometric configuration can be one kind of polygon, such as a rectangle, and the second geometric configuration can be another kind of polygon, such as a triangle. However, in many embodiments of the disclosure, both the first and the second geometric configuration are rectangles, although with different absolute sizes and/or different ratios between the length of one side and the length of an adjacent side, that is, with different aspect ratios. In many embodiments of the disclosure, the difference between the first geometric configuration and the second geometric configuration resides in the ratio between length and width of the rectangle.

Dividing the wafer into a plurality of solar cells having different geometrical configurations makes it possible to enhance wafer utilization: a larger percentage of the total effective solar cell surface of the wafer can be used to actually produce solar cells; the amount of waste is reduced. Thus, the disclosure provides for enhanced efficiency in the use of the material of the wafer for the production of solar cells, while allowing at least some of the solar cells to maintain a relatively substantial size.

Thus, some embodiments of the disclosure relate to a method to divide a circular wafer that makes it possible to obtain, for example, a final rectangular CIC with high wafer utilization. Production of solar cell wafers for high-efficiency solar cells, such as III/V semiconductor solar cells, is often a relatively costly procedure. Thus, efficient use of the material is an advantage.

Thus, in some embodiments of the disclosure an epitaxially grown solar cell structure on a circular wafer can be divided into a multiplicity of smaller solar cells of different dimensions and/or shapes. The smaller solar cells can be, for example, rectangular. The division can be performed to provide a high percentage of wafer utilization. The smaller rectangular solar cells can be rearranged into a configuration such as a large rectangle. Some or all of the small rectangular solar cells from one wafer can be included in the arrangement of the large rectangle.

In some embodiments of the disclosure, the at least one solar cell having a first geometric configuration has a rectangular shape and a first size, and the at least one solar cell having a second geometric configuration has a rectangular shape and a second size, the second size being different from the first size. As the assembly to be obtained, such as for example a CIC assembly, often should have a rectangular shape, making the individual solar cells rectangular may facilitate assembly. It can often be easy to assemble individual rectangular solar cells so as to form a rectangular assembly.

In some embodiments of the disclosure, the first size is a multiple of the second size. This makes it easy to assemble the solar cells of different sizes to form an assembly having a rectangular, for example square, shape. The rectangle of the assembly can have a width and a height corresponding to a multiple of the first size.

In some embodiments of the disclosure, the plurality of solar cells further comprises at least one solar cell having a rectangular shape and a third size, the third size being different from the first size and the second size, the first size being a multiple of the third size. Also here it will be easy to form an assembly having a rectangular shape, by combining solar cells having the three, or more, different sizes. This can be easily understood from, for example, FIG. 2, which shows an example of this kind of arrangement.

In some embodiments of the disclosure, the at least one solar cell having the first geometric configuration is shaped as a rectangle having a first length and a first width, and the at least one solar cell having a second geometric configuration is shaped as a rectangle having a second length and a second width, wherein the first length is equal to the second length, and the first width is different from the second width, or the first length is different from the second length, and the first width is equal to the second width.

For example, if the solar cells all have substantially the same length, they can all fit into aligned rows, such as schematically illustrated in FIG. 2, where all of the vertical columns of solar cells have the same width corresponding to the length of the individual solar cells included therein. The different columns can, nevertheless, feature different numbers of solar cells, due to the fact that the solar cells feature different widths.

In some embodiments of the disclosure, the plurality of solar cells comprise m solar cells having the first geometric configuration, and n solar cells having the second geometric configuration, m and n both being integers larger than 10, preferably larger than 20. Dividing the waver into a relatively large number of solar cells can enhance the efficient use of the material, reducing waste.

A second aspect of the disclosure relates to a method of producing a solar cell assembly, comprising the step of producing a plurality of solar cells with the method described above, and arranging a set of solar cells including at least one of the plurality of solar cells, so as to form an assembly of solar cells, the assembly of solar cells having a substantially rectangular configuration. As explained above, obtaining the assembly in this way is useful to enhance efficient use of the wafer, and to reduce waste. A rectangular assembly can be produced out of, for example, one or more substantially circular wafers, with high wafer efficiency.

In some embodiments of the disclosure, the set of solar cells forming the assembly comprises more than one solar cell of said plurality of solar cells, that is, more than one solar cell coming from the same wafer. In some embodiments of the disclosure, the set of solar cells comprises only solar cells selected from said plurality of solar cells, that is, originating from one and the same wafer. This can sometimes be useful to provide for homogeneity of the solar cells used in the assembly: homogeneity in what regards certain aspects can be easier to achieve and guarantee if all the solar cells are obtained from one and the same wafer.

In some embodiments of the disclosure, the method comprises the step of interconnecting at least some solar cells of said set of solar cells in a series connection comprising at least a first stage and a second stage connected in series, the first stage comprising a different number of solar cells than the second stage. In some embodiments of the disclosure, an effective surface area of the first stage and an effective surface area of the second stage have substantially the same size. That is, in terms of total size, the effective surface area of the first stage is substantially the same as the effective surface area of the second stage. The term “effective surface area” refers to the total surface area of the cell or cells of the stage that is useful for producing electrical energy. For example, the first stage can comprise one solar cell having a first, larger, surface area, and the second stage can comprise two solar cells each having a surface area which is approximately 50% of the first, larger, surface area. This kind of arrangement can, for example, allow solar cells of different sizes to be built up into a high voltage solar cell sub-assembly without limiting the short-circuit current of the sub-assembly to the short-circuit current of the smallest solar cell.

A third aspect of the disclosure relates to a solar cell assembly comprising a plurality of solar cells, the solar cell assembly having a rectangular configuration, the solar cells having a rectangular shape, wherein a plurality of the solar cells have a first size and plurality of said solar cells have a second size different from said first size, said first size being a multiple of said second size. As explained above, this allows for efficient use of the material of a non-rectangular, such as a substantially circular, wafer, when constructing a rectangular solar cell assembly.

In some embodiments of the disclosure, the first set of solar cells have a first size, a first length and a first width, and the second set of solar cells have a second size, a second length and a second width, wherein the first length is equal to the second length, and the first width is different from the second width, or the first length is different from the second length, and the first width is equal to the second width. As explained above, this arrangement can facilitate the production of assemblies of solar cells with rows and columns made up of solar cells having different sizes.

In some embodiments of the disclosure, at least some of the solar cells are connected in a series connection comprising at least a first stage and a second stage connected in series, the first stage comprising a different number of solar cells than the second stage. In some embodiments of the disclosure, an effective surface area of the first stage and an effective surface area of the second stage have substantially the same size, that is, the total effective surface area of the first stage is substantially the same as the total effective surface area of the second stage. As explained above, the term “effective surface area” refers to the total surface area of the cell or cells of the stage that is useful for producing electrical energy. For example, one stage can comprise one solar cell having a first, larger, surface area, and the second stage can comprise two solar cells each having a surface area which is approximately 50% of the first, larger, surface area. This kind of arrangement can, for example, allow solar cells of different sizes to be built up into a high voltage solar cell sub-assembly without limiting the short-circuit current of the sub-assembly to the short-circuit current of the smallest solar cell.

### BRIEF DESCRIPTION OF THE DRAWINGS

To complete the description and in order to provide for a better understanding of the disclosure, a set of drawings is provided. Said drawings form an integral part of the description and illustrate an embodiment of the disclosure, which should not be interpreted as restricting the scope of the disclosure, but just as an example of how the disclosure can be carried out. The drawings comprise the following figures:

FIG. 1 is a top view of a substantially circular solar cell wafer, with lines indicating how the wafer can be divided into individual solar cells having different geometric configurations in terms of size and shape, according to an embodiment of the disclosure.

FIG. 2 schematically illustrates how a rectangular solar cell assembly can be composed of solar cells obtained by a method according to an embodiment of the disclosure.

FIG. 3 schematically illustrate a two-stage series connection of solar cells in accordance with an embodiment of the disclosure.

### DETAILED DESCRIPTION

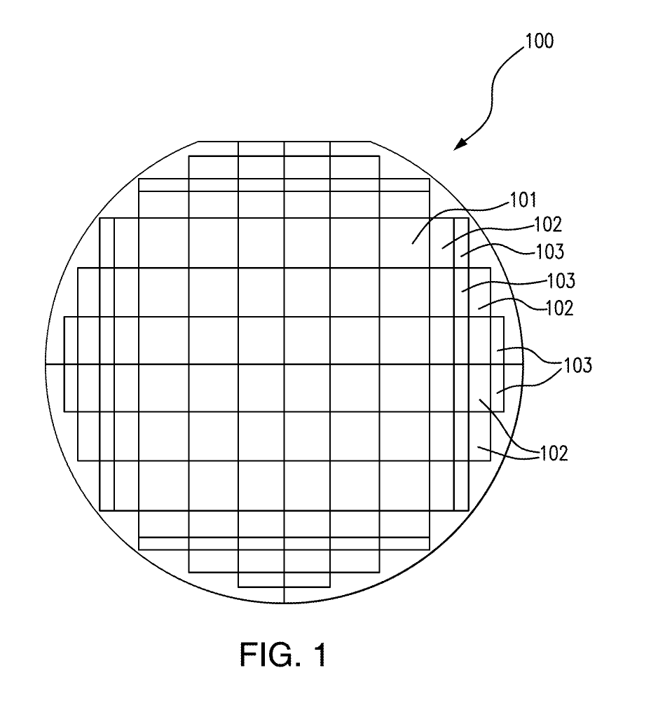

Referring to FIG. 1, a plurality of discrete semiconductor solar cells can be fabricated by dicing a circular wafer 100. In some embodiments, the wafer can be, for example, germanium or gallium arsenide, and the solar cell may be a multijunction device made of III/V semiconductor materials. The junctions may be lattice matched to the wafer substrate or may be lattice mismatched with respect to each other. For lattice mismatched solar cells, the solar cells may be grown using metamorphic buffer layers to reduce strain.

The fabricated wafer 100 can be divided into a plurality of solar cells 101, 102 and 103, having three different geometrical configurations. In the illustrated embodiments, the solar cells 101, 102 and 103 all have a rectangular shape and the same length, but they have different sizes, due to different length to width ratios. Thus, they have different rectangular shapes.

Several solar cells 101 have a first geometric configuration, namely, a square configuration with a first size. The solar cells 102 have a second geometrical configuration, namely, a rectangular configuration with a width that is smaller than the height, namely, about 50% of the height. Thus, the solar cells 102 have a second size, the first size of the solar cells 101 being twice the second size of the solar cells 102.

The solar cells 103 have the same height as the solar cells 101 and 102, but their width is only 50% of the widths of the solar cells 102. That is, the solar cells 103 have a third size and the first size is four times the third sizes.

Obviously, this is just an example and other solar cell layouts are possible.

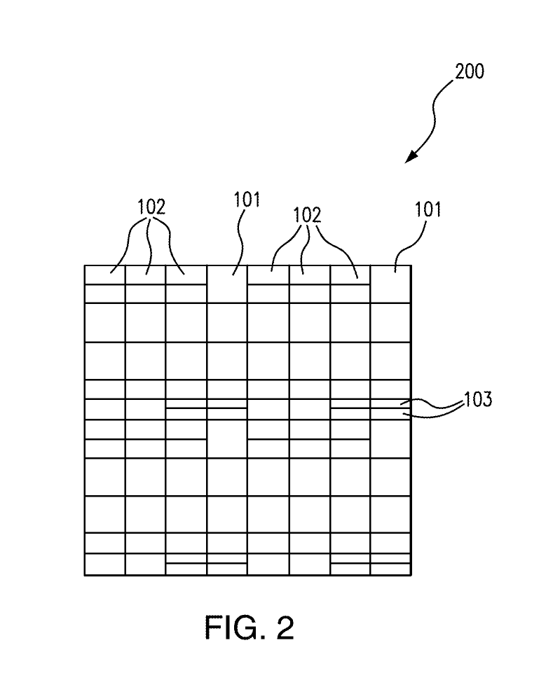

After dicing, the rectangular cells 101, 102, and 103 can then be rearranged onto a substrate into a rectangular configuration. A possible layout for the assembly of the solar cells 101, 102, and 103 in to a rectangular assembly 200 is shown in FIG. 2, where the solar cells 101, 102 and 103 have been assembled side by side so as to form a rectangle, made up of solar cells all having a rectangular shape but having three different sizes. Of course, any number of different size cells may be used and reconfigured. In some embodiments of the disclosure, all of the cells used to form the rectangle come from the same wafer. In other embodiments of the disclosure, solar cells made from different wafers are used to form the rectangle.

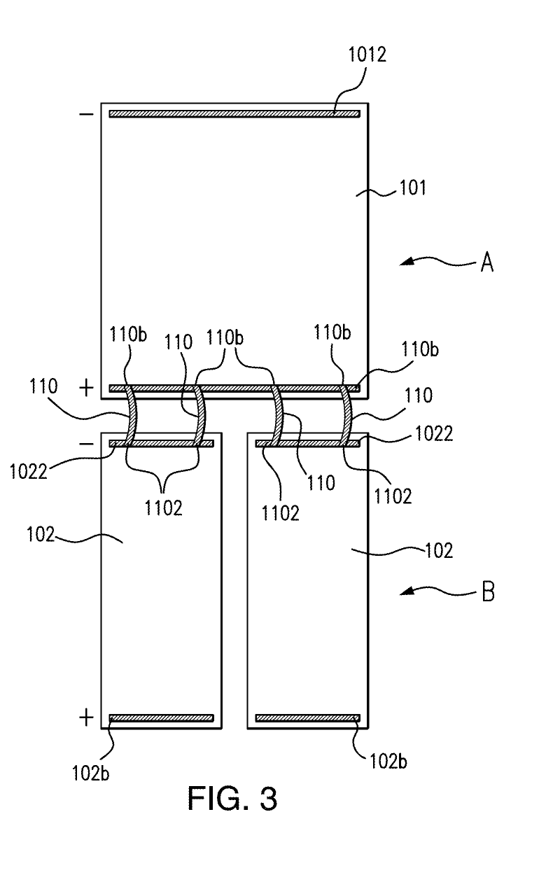

In some embodiments of the disclosure, the solar cells are assembled in series to produce a solar cell subassembly with a desired voltage, such as a relatively high voltage, higher than the one produced by the individual solar cells. The open-circuit voltage of the high-voltage sub-assembly will be the number of solar cells connected in series times the open-circuit voltage of the individual solar cells. If the solar cells are of multiple sizes, then multiple smaller solar cells can be connected in series to a single larger solar cell. For example, in the embodiment illustrated in FIG. 3, two solar cells having a second size are connected in series to one single solar cell 101 having a first size, the first size being twice the second size. FIG. 3 illustrates two rectangular solar cells 102 connected in series with a square solar cell 101, the width of the square solar cell 101 being approximately twice the width of each of the rectangular solar cells 102.

Thus, FIG. 3 illustrates a two-stage serial connection of solar cells, the first stage A comprising one solar cell and the second stage B comprising two solar cells 102. A sub-assembly of solar cells can, in some embodiments of the disclosure, be made up of two or more stages connected in series, each stage being made up of one or more solar cells of different sizes. This kind of configuration allows solar cells of different sizes to be built up into a high voltage solar cell sub-assembly without limiting the short-circuit current of the sub-assembly to the short-circuit current of the smallest component solar cell.

The electrical polarity of the solar cell contact pads 101a (negative), 101b (positive), 102a (negative) and 102b (positive) is indicated in FIG. 3. More specifically, the solar cell 101 is provided with bonding pads 101a and 101b on the top surface; connectors 110 are coupled to the bonding pad 101b at one end 110b and coupled to respective solar cells 102 by means of the other end 110a of said connectors 110 being coupled to the contacts pads 102a of solar cells 102a. A cover glass (not shown) can be disposed over the solar cell 101 and the end portion 110b of the connectors 110. The connectors 110 generally are formed of metal or metal alloy, and may often be referred to as “interconnectors” in the art. The solar cell assembly may be referred as interconnected solar cells (“ICs”), or glass-covered and interconnected solar cell (“CICs”) in the case that the ICs are covered with glass covers.

In this text, the term “rectangle” encompasses the term “square”, that is, the term “square” is used to refer to a subset of “rectangular”.

In this text, the term “comprises” and its derivations (such as “comprising”, etc.) should not be understood in an excluding sense, that is, these terms should not be interpreted as excluding the possibility that what is described and defined may include further elements, steps, etc.

On the other hand, the disclosure is obviously not limited to the specific embodiment(s) described herein, but also encompasses any variations that may be considered by any person skilled in the art (for example, as regards the choice of materials, dimensions, components, configuration, etc.), within the general scope of the disclosure as defined in the claims.

1. A method for producing solar cells, comprising the step of dividing a non-rectangular solar cell wafer into a plurality of solar cells, said plurality of solar cells comprising at least one solar cell having a first geometric configuration and at least one solar cell having a second geometric configuration, the second geometric configuration being different from the first geometric configuration.

2. The method of claim 1, wherein the at least one solar cell having the first geometric configuration has a rectangular shape and a first size, and wherein the at least one solar cell having the second geometric configuration has a rectangular shape and a second size, the second size being different from the first size.

3. The method of claim 2, wherein the first size is a multiple of the second size.

4. The method of claim 2, wherein the plurality of solar cells further comprises at least one solar cell having a rectangular shape and a third size, the third size being different from the first size and the second size, the first size being a multiple of the third size.

5. The method of claims 2, wherein the at least one solar cell having the first geometric configuration is shaped as a rectangle having a first length and a first width, and wherein the at least one solar cell having the second geometric configuration is shaped as a rectangle having a second length and a second width, wherein
the first length is equal to said second length, and the first width is different from the second width, or
the first length is different from the second length, and the first width is equal to the second width.

6. The method claim 1, wherein the plurality of solar cells comprise m solar cells having the first geometric configuration, and n solar cells having the second geometric configuration, m and n both being integers larger than 10, preferably larger than 20.

7. A method of producing a solar cell assembly, comprising the steps of:
producing a plurality of solar cells with the method according to claim 1, and
arranging a set of solar cells including at least one of the plurality of solar cells, so as to form an assembly of solar cells, the assembly having a substantially rectangular configuration.

8. The method of claim 7, wherein the set of solar cells comprises more than one solar cell of the plurality of solar cells.

9. The method of claim 7, wherein the set of solar cells comprises only solar cells selected from the plurality of solar cells.

10. The method of claim 7, comprising the step of interconnecting at least some solar cells of the set of solar cells in a series connection comprising at least a first stage and a second stage connected in series, the first stage comprising a different number of solar cells than the second stage.

11. The method of claim 10, wherein an effective surface area of the first stage and an effective surface area of the second stage have substantially the same size.

12-15. (canceled)
